(19) United States
(12) Patent Application Publication
(10) Pub. No.: US 2015/0068795 A1
(43) Pub. Date: Mar. 12, 2015

(54) SUBSTRATE WITH BUILT-IN ELECTRONIC COMPONENT AND CORE BASE-MATERIAL FOR SUBSTRATE WITH BUILT-IN ELECTRONIC COMPONENT

(71) Applicant: Taiyo Yuden Co., Ltd., Tokyo (JP)

(72) Inventors: Kazuaki IDA, Gunma (JP); Masashi MIYAZAKI, Tokyo (JP); Tatsuro SAWATARI, Tokyo (JP); Hiroshi NAKAMURA, Tokyo (JP); Masaki NAGANUMA, Tokyo (JP)

(73) Assignee: Taiyo Yuden Co., Ltd., Tokyo (JP)

(21) Appl. No.: 14/103,639

(22) Filed: Dec. 11, 2013

(30) Foreign Application Priority Data
Sep. 12, 2013 (JP) 2013-189179

(51) Int. Cl. H05K 1/18

(52) U.S. Cl. CPC H05K 1/183
USPC 174/260

(57) ABSTRACT

A substrate with built-in electronic component includes an electronic component, a first wiring layer, a second wiring layer, a via, and a core base-material. The first wiring layer has a first wiring portion. The second wiring layer has a second wiring portion. The via is configured to electrically connect the first wiring portion and the second wiring portion. The core base-material has a metal layer, at least one first storage portion, and a second storage portion, the metal layer being disposed between the first wiring layer and the second wiring layer, the at least one first storage portion being formed in the metal layer, the at least one first storage portion storing the electronic component, the second storage portion being formed on an outside of the first storage portion integrally with the first storage portion, the second storage portion storing the via.

### CROSS-REFERENCE TO A RELATED APPLICATION

This application claims priority under 35 U.S.C. §119 to Japanese Patent Application No. JP 2013-189179 filed on Sep. 12, 2013, the entire content of which is hereby incorporated herein by reference in its entirety

### FIELD

The present disclosure relates to a substrate with built-in electronic component including a metal core having an electronic component storage portion and to a core base-material for substrate with built-in electronic component.

### BACKGROUND

With the substrate with built-in electronic component, it is possible to increase the mounting density and to reduce the size of the substrate as compared with the existing substrate with built-in electronic component. Thus, the substrate with built-in electronic component contributes to the size reduction and thinning of a portable apparatus such as a mobile phone, a portable electronic dictionary, and a digital camera.

For example, Japanese Patent Application Laid-open No. 2010-177713 discloses a multilayer substrate with built-in electronic component including a core in which a hole portion storing an electronic component or a penetrating hole for through-hole are formed. The electronic component fixed in the hole portion is connected to a wiring layer outside of the core via a via, and two wiring layers sandwiching the core are electrically connected to each other via the through-hole.

### SUMMARY

With the size reduction and multifunction of electronic apparatuses in recent years, it is expected to further reduce the size of a wiring substrate or package component mounted on an electronic apparatus and to high-density mount the wiring substrate or package component. However, if a hole portion for storing component and a penetrating hole for forming through-hole are formed in a core independently, it is difficult to reduce the size of the core and to make the wiring density high. Furthermore, because the hole portion and the penetrating hole often have significantly different aperture areas, it causes a problem where it may be impossible to form the hole portion and the penetrating hole uniformly in a plane due to the variability of the etching rate, for example, and it is more difficult to reduce the size of the core or to high-density mount the core.

In view of the circumstances as described above, it is desirable to provide a substrate with built-in electronic component and a core base-material for substrate with built-in electronic component, which are capable of reducing the size of a core or high-density mounting the core.

According to an embodiment of the present disclosure, there is provided a substrate with built-in electronic component including an electronic component, a first wiring layer, a second wiring layer, a via, and a core base-material.

The first wiring layer has a first wiring portion.

The second wiring layer has a second wiring portion.

The via is configured to electrically connect the first wiring portion and the second wiring portion.

The core base-material has a metal layer, at least one first storage portion, and a second storage portion, the metal layer being disposed between the first wiring layer and the second wiring layer, the at least one first storage portion being formed in the metal layer, the at least one first storage portion storing the electronic component, the second storage portion being formed on an outside of the first storage portion integrally with the first storage portion, the second storage portion storing the via.

Moreover, according to an embodiment of the present disclosure, there is provided a core base-material for substrate with built-in electronic component disposed between a first wiring layer and a second wiring layer, including a metal layer, at least one first storage portion, and a second storage portion.

The at least one first storage portion is capable of storing an electronic component, the at least one first storage portion being formed in the metal layer.

The second storage portion is capable of storing a via, the second storage portion being formed on an outside of the first storage portion integrally with the first storage portion, the via being configured to electrically connect the first wiring layer and the second wiring layer.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIGS. 1A and 1B are each a diagram showing the structure of a substrate with built-in electronic component according to a first embodiment of the present disclosure, FIG. 1A is a horizontal cross-sectional view of an electronic component storage portion of the substrate with built-in electronic component, and FIG. 1B is a vertical cross-sectional view taken along the line [B]-[B] of FIG. 1A;

FIGS. 2A-2E are each a process cross-sectional view schematically showing a method of producing the substrate with built-in electronic component;

FIGS. 3A-3D are each a vertical cross-sectional view showing a modified example of the configuration of the electronic component storage portion;

FIG. 4 is a horizontal cross-sectional view of a main portion showing the structure of a substrate with built-in electronic component according to a second embodiment of the present disclosure;

FIG. 5 is a horizontal cross-sectional view of a main portion showing a modified example of the structure of the substrate with built-in electronic component according to the second embodiment of the present disclosure;

FIG. 6 is a horizontal cross-sectional view of a main portion showing another modified example of the structure of the substrate with built-in electronic component according to the second embodiment of the present disclosure; and

FIG. 7 is a horizontal cross-sectional view of a main portion showing the structure of a substrate with built-in electronic component according to a third embodiment of the present disclosure.

### DETAILED DESCRIPTION OF EMBODIMENTS

A substrate with built-in electronic component according to an embodiment of the present disclosure includes an electronic component, a first wiring layer, a second wiring layer, a via, and a core base-material.

The first wiring layer has a first wiring portion.

The second wiring layer has a second wiring portion.

The via is configured to electrically connect the first wiring portion and the second wiring portion.

The core base-material has a metal layer, at least one first storage portion, and a second storage portion, the metal layer being disposed between the first wiring layer and the second wiring layer, the at least one first storage portion being formed in the metal layer, the at least one first storage portion storing the electronic component, the second storage portion being formed on an outside of the first storage portion integrally with the first storage portion, the second storage portion storing the via.

According to the substrate with built-in electronic component, because the first storage portion storing the electronic component and the second storage portion storing the via are integrally formed, it is possible to reduce the size of the core and to make the wiring density high. Moreover, because a second storage portion 12 is formed on the outside of a first storage portion 11, it is possible to cause a via 5 to come close to an electronic component 2 while securing a storage area for the electronic component 2. Accordingly, it is possible to high-density mount a surface mount component while securing the mounting reliability of the electronic component 2.

Furthermore, because it is possible to reduce the distribution of the density of the aperture area or variability of the etching rate in the case where each storage portion is formed on the core base-material by a wet etching method, for example, consistent process accuracy is easily ensured in a plane. Accordingly, it is possible to obtain a sophisticated small-sized core base-material.

The position at which the second storage portion is provided is not particularly limited, and can be appropriately set depending on the shape of the first storage portion or the like.

For example, the first storage portion may have a first aperture having a substantially rectangular shape, and the second storage portion may have a second aperture formed on at least one side portion of the first aperture. A plurality of second storage portions may be formed on a side portion of the first aperture. Accordingly, it is possible to make the density of the storage portion further high.

Alternatively, the first storage portion may have a first aperture having a substantially rectangular shape, and the second storage portion may have a second aperture formed on at least one corner portion of the first aperture.

The first storage portion is typically formed by wet etching of a predetermined area of the metal layer. Therefore, if the aperture of the first storage portion has a rectangular shape, the four corners of the aperture are easily formed to have a circular arc shape. Thus, the capacity of the first storage portion is reduced, and the area of the aperture is reduced. Therefore, it is difficult to ensure a predetermined clearance between the four corners of the aperture and the outer peripheral surface of the electronic component (e.g., angular portion).

In this regard, the core base-material may further have a third aperture formed on at least one corner portion of the first aperture, the third aperture having an aperture area smaller than the second aperture.

Accordingly, it is possible to easily perform the operation of mounting (storing) the electronic component in the first storage portion, and to ensure a predetermined clearance (minimum space) between the inner peripheral surface of the first storage portion and the outer peripheral surface of the electronic component after the mounting.

The first storage portion may have two first storage portions facing each other in a first axis direction, and the third aperture may be formed so as to project from the corner portion of the first aperture to a second axis direction perpendicular to the first axis direction.

Accordingly, it is possible to make the space between the two first storage portions minimum, and to make the density of the storage portion high.

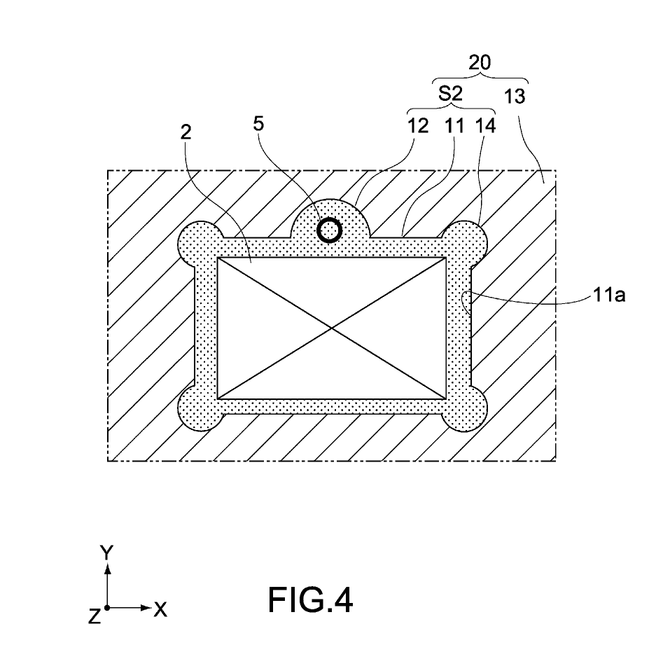

Here, “project to a second axis direction perpendicular to the first axis direction” means that the central point of the third aperture (e.g., auxiliary aperture 14 shown in FIG. 4) does not exist in the direction of the angle of 45 degrees with respect to the first axis direction. The end portion of the third aperture is favorably located on the same plane with the end portion of the first storage portion along the second axis direction. In this way, it is possible to make the effective area efficiency further high.

Moreover, a core base-material for substrate with built-in electronic component disposed between a first wiring layer and a second wiring layer according to an embodiment of the present disclosure includes a metal layer, at least one first storage portion, and a second storage portion.

The at least one first storage portion is capable of storing an electronic component, the at least one first storage portion being formed in the metal layer.

The second storage portion is capable of storing a via, the second storage portion being formed on an outside of the first storage portion integrally with the first storage portion, the via being configured to electrically connect the first wiring layer and the second wiring layer.

According to the core base-material for substrate with built-in electronic component, because the first storage portion storing the electronic component and the second storage portion storing the via are integrally formed, it is possible to reduce the size of the core and to make the wiring density high.

Moreover, because it is possible to reduce the distribution of the density of the aperture area in the case where each storage portion is formed on the core base-material by a wet etching method, for example, consistent process accuracy is easily ensured in a plane. Accordingly, it is possible to obtain a sophisticated small-sized core base-material.

The first storage portion may have a first aperture having a substantially rectangular shape, the second storage portion may have a second aperture formed on one of at least one side portion and at least one corner portion of the first aperture, and the core base-material for substrate with built-in electronic component may further have a third aperture being formed on the at least one corner portion of the first aperture, the third aperture having an aperture area smaller than the second aperture.

Accordingly, it is possible to easily perform the operation of mounting (storing) the electronic component in the first storage portion, and to ensure a predetermined clearance (minimum space) between the inner peripheral surface of the first storage portion and the outer peripheral surface of the electronic component after the mounting.

Hereinafter, a substrate with built-in electronic component according to an embodiment of the present disclosure will be described with reference to the drawings.

### First Embodiment

[Configuration of Substrate with Built-in Electronic Component]

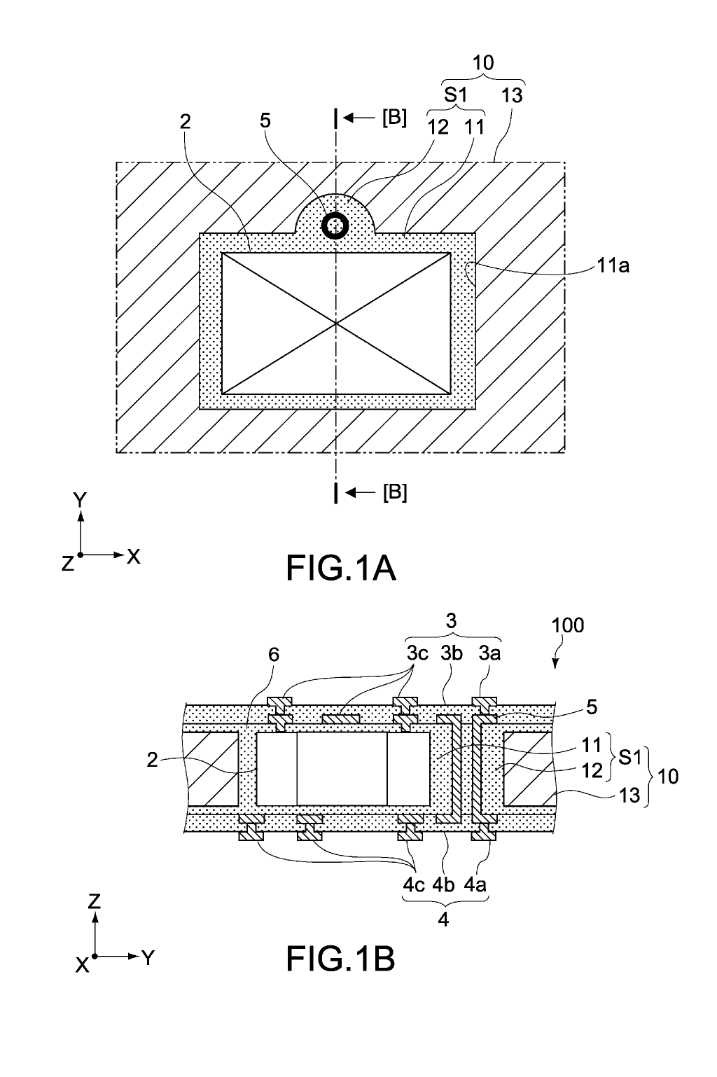

FIGS. 1 are each a diagram showing the structure of a substrate with built-in electronic component according to a first embodiment of the present disclosure, FIG. 1A is a horizontal cross-sectional view of a main portion, and FIG. 1B is a vertical cross-sectional view taken along the line [B]-[B] of FIG. 1A.

It should be noted that in each figure, X-, Y-, and Z-axes represent triaxial directions orthogonal to each other, and the Z-axis direction (vertical direction) corresponds to the thickness direction of the substrate. It should be noted that the configuration of each portion is exaggeratingly shown in order to facilitate understanding, and the sizes of the members or the ratios of the sizes of the members do not necessarily correspond to each other in the figures.

A substrate with built-in electronic component 100 according to this embodiment has the electronic component 2, a first wiring layer 3, a second wiring layer 4, the via 5, and a core base-material 10, and a predetermined electrical/electronic circuit including the electronic component 2 is structured three-dimensionally. The size or shape of the substrate with built-in electronic component is not particularly limited. However, the substrate with built-in electronic component may have a rectangular parallelepiped shape of several ten mm square and a thickness of several mm, for example.

### Electronic Component

The electronic component 2 is disposed in the first storage portion 11 formed on a metal layer 13 of the core base-material 10. The electronic component 2 is electrically connected to a wiring portion 3c of the first wiring layer 3 in FIGS. 1. Typically, the electronic component 2 includes a capacitor, an inductor, a resistor, a filter chip, or an integrated circuit component such as an integrated circuit (IC). In the case of the integrated circuit component, it may be face-up fixed, i.e., the terminal surface is directed upward, or may be face-down fixed, i.e., the terminal surface is directed downward. The size or shape of the electronic component 2 is not particularly limited. However, in this embodiment, the electronic component 2 has a substantially rectangular parallelepiped shape.

### First and Second Wiring Layers

The first wiring layer 3 is formed on the upper portion of the core base-material 10, has a wiring portion 3a, an insulating layer 3b, and the wiring portion 3c, and the wiring portion 3a and the wiring portion 3c are laminated via the insulating layer 3b. On the other hand, the second wiring layer 4 is formed on the lower portion of the core base-material 10, has a wiring portion 4a, an insulating layer 4b, and a wiring portion 4c, and the wiring portion 4a and the wiring portion 4c are laminated via the insulating layer 4b. On the wiring portions 3c and 4c being the outermost layer, a land on which a surface mount component (not shown) is mounted is formed.

Here, the wiring portion 3a and the wiring portion 4a correspond to the first wiring portion and the second wiring portion electrically connected to each other via the via 5, respectively. However, the form of the wiring is not limited to the example shown in FIGS. 1.

Each wiring portion formed on the first wiring layer 3 and the second wiring layer 4 typically includes, but not limited to, a copper foil patterned into a predetermined shape. Typically, examples of the material forming the insulating layers 3b and 4b include BT resin (bismaleimide triazine resin) or a glass epoxy material. However, the material forming the insulating layers 3b and 4b is not limited thereto, and an insulating ceramic material or the like can be employed.

### Via

The via 5 is formed in the second storage portion 12 formed on the metal layer 13 of the core base-material 10, and includes a through-hole electrically connecting the wiring portion 3a and the wiring portion 4a. The via 5 typically includes, but not limited to, a conductor such as a copper plating formed in an insulating layer 6 in the second storage portion 12, and may include a conductor plug obtained by filling a conductor in the via.

### Core Base-Material

The core base-material 10 has the metal layer 13, the at least one first storage portion 11 capable of storing the electronic component 2, and the second storage portion 12 capable of storing the via 5.

The thickness or shape of the metal layer 13 is not particularly limited. For example, the metal layer 13 has a thickness capable of storing the electronic component 2, and typically has a substantially rectangular shape. As the material forming the metal layer 13, a conductive material such as copper and a copper alloy can be employed. For example, the metal layer 13 is connected to a ground potential via one of the wiring portions. The metal layer 13 has a function to increase the rigidity of the substrate with built-in electronic component and to protect the electronic component 2. Moreover, it is possible to increase the heat radiation property with the metal layer 13.

The electronic component 2 is disposed in the first storage portion 11, and the via 5 is formed in the second storage portion 12. In order to avoid electrical connection with the core base-material 13, the insulating layer 6 covers around the electronic component 2 and the via 5. The insulating layer 6 is formed in the first and second storage portions 11 and 12 and on each surface of the core base-material 13, and the first and second wiring layers 3 and 4 are laminated on each surface of the core base-material 13 via the insulating layer 6. The insulating layer 6 may be additionally formed in the via 5. The insulating layer 6 includes an insulating resin material or an inorganic material. To the resin material, a filler such as silica and alumina may be added.

In this embodiment, the first storage portion 11 has an aperture 11a (first aperture) having a substantially rectangular shape, and can be formed by performing a wet etching process or the like on the metal layer 13. In this embodiment, the first storage portion 11 is formed as a penetrating hole. However, the first storage portion 11 may be formed as a concave portion having a depth such that the electronic part 2 can be disposed and the first storage portion 11 does not penetrate the metal layer 13. The shape of the first storage portion 11 can be selected at any time depending on the shape of the electronic component 2 and the designing of the substrate. Moreover, the first storage portion 11 may be formed by physical processing using a drill or the like or laser processing.

The second storage portion 12 is formed on the outside of the aperture 11 a of the first storage portion 11 integrally with the first storage portion 11, and can be formed by performing a wet etching process or the like on the metal layer 13. As shown in FIGS. 1, the second storage portion 12 includes an aperture (second aperture) formed on the outside of a side portion (long side portion in this example) of the aperture 11 a of the first storage portion 11, which has a circular arc shape, in this embodiment. The shape of the second storage portion 12 is a hole penetrating in the thickness direction of the core base-material 10, and the width of the second storage portion 12 is not particularly limited as long as the via 5 to be stored in the second storage portion 12 is not brought into contact with the metal layer 13. Moreover, the second storage portion 12 may be formed by physical processing using a drill or the like or laser processing.

The first storage portion 11 and the second storage portion 12 form a cavity 51 formed on the metal layer 13. The cavity 51 may be formed at any position in a plane of the metal layer 13, and is typically formed at the central part of the metal layer 13. The number of the cavity 51 is not particularly limited, and a plurality of cavities 51 may be formed in the plane of the metal layer 13.

[Method of Producing Substrate with Built-in Electronic Component]

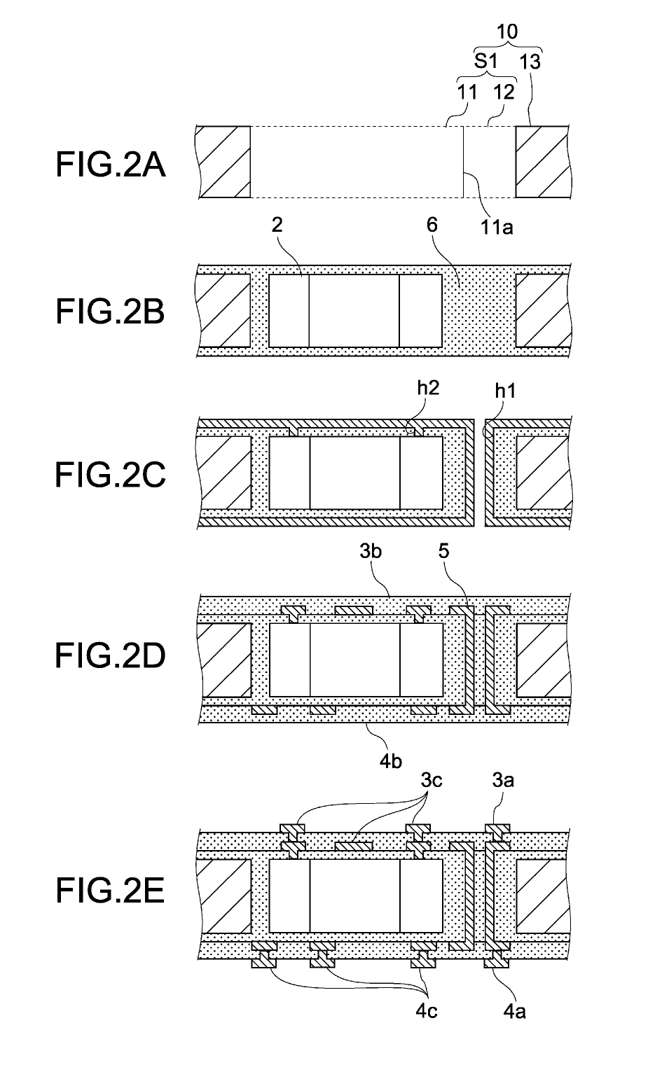

FIGS. 2 are each a schematic diagram showing a method of producing the substrate with built-in electronic component according to this embodiment. It should be noted that a plurality of substrates with built-in electronic component are produced on a substrate, and divided into each substrate with built-in electronic component. However, hereinafter, one substrate with built-in electronic component will be described. It should be noted that the following description will be given for illustrative purposes and the method of producing the substrate with built-in electronic component is not limited thereto.

First, the core base-material 10 having a penetrating hole or a concave portion is prepared. As shown in FIG. 2A, etching processing, physical processing using a drill or the like, laser processing, or the like is applied on a metal plate to form the first storage portion 11, and the second storage portion 12 is formed on the outside of a side portion of the aperture 1 la of the first storage portion 11, which has a substantially rectangular shape, so that the storage portions are integrally formed. Accordingly, the core base-material 10 having the cavity 51 and the metal layer 13 is produced.

In this embodiment, the cavity 51 is formed by a wet etching method. At this time, a resist pattern in which forming parts of the first and second storage portions 11 and 12 are opened is formed on the surface of the metal layer 13, and the first and second storage portions 11 and 12 (cavity 51) are integrally formed using the resist pattern as a mask.

The etching solution is not particularly limited, and ammonia water, potassium dichromate, chromic anhydride, ferric chloride, ammonium persulfate, sodium hydroxide, or the like can be applied.

The cavity S1 is typically formed as a penetrating hole. In this case, an etching process may be applied to one surface of the metal layer 13 to form the cavity S1, or an etching process may be applied to both surfaces of the metal layer 13 to form the cavity S1.

Next, the core base-material 10 in which the cavity S1 is formed is disposed and tentatively fixed on an adhesive sheet (not shown). Then, after the electronic component 2 is mounted in the first storage portion 11 of the cavity S1, a liquid insulating material is filled on the adhesive material and is cured. Furthermore, the adhesive sheet is removed, and an insulating material is applied on the side on which the adhesive sheet is removed and is cured.

Accordingly, as shown in FIG. 2B, the structure in which the electronic component 2 and the core base-material 10 are embedded in the insulating layer 6 is achieved.

Next, as shown in FIG. 2C, a penetrating hole h1 for forming the via 5 and a contact hole h2 for the electronic component 2 are formed by applying a laser beam such as a YAG laser and a CO₂ laser to the insulating layer 6. The penetrating hole h1 is formed by applying a laser beam from right above the second storage portion 12 of the cavity S1 to the direction perpendicular to the upper surface of the insulating layer 6. The contact hole h2 is formed by applying a laser beam from right above the electrode of the electronic component 2 to the direction perpendicular to the upper surface of the insulating layer 6.

Next, the via 5 and the wiring portions (a part of the wiring portions 3c and 4c) by immersing the metal layer 13 in a plating solution and plating both surfaces of the metal layer 13 and the inner wall surfaces of the penetrating hole h1 and the contact hole h2 with a conductive material. The penetrating hole in the via 5 may be filled with a conductive material. Alternatively, the insulating layer 6 may be formed in the via 5 by filling an insulating material in the penetrating hole in the via 5.

Next, the first wiring layer 3 is formed on the upper surface of the core base-material 10, and the second wiring layer 4 is formed on the lower surface of the core base-material 10. First, on the upper and lower surfaces of the core base-material 10, a conductor film is formed by a plating method, a sputtering method, or the like. Then, as shown in FIG. 2D, a part of the wiring portion having the first wiring layer 3 and the second wiring layer 4 is formed by applying an etching process to the conductor film so that it has a predetermined shape. Next, a liquid insulating material is applied to the upper and lower surfaces of the core base-material 10 on which the conductor film is formed, and thus, the insulating layers 3b and 4b are formed.

Furthermore, as shown in FIG. 2E, a via hole is formed in the insulating layers 3b and 4b by the above-mentioned method, and a via is formed by a plating method or the like. Next, the conductor film is formed by the above-mentioned method, and an etching process is applied to the conductor film so that it has a predetermined shape. Accordingly, the wiring portion 3a, the wiring portion 3c, the wiring portion 4a, and the wiring portion 4c are formed, and the first wiring layer 3 and the second wiring layer 4, which have a structure in which each wiring portion and insulating layer is laminated is formed on the upper and lower surfaces of the core base-material 10.

### Operation of This Embodiment

The substrate with built-in electronic component is formed through the processes. According to this embodiment, because the core base-material 10 has the cavity S1 in which the first storage portion 11 storing the electronic component 2 and the second storage portion 12 storing the via 5 are integrally formed, it is possible to reduce the size of the core base-material 10 and to make the wiring density high.

Moreover, because the second storage portion 12 is formed on the outside of the first storage portion 11, it is possible to cause the via 5 to come close to the electronic component 2 while securing a large storing area of the electronic component 2. Accordingly, it is possible to high-density mount a surface mount component while securing the mounting reliability of the electronic component 2.

Furthermore, according to this embodiment, because the cavity S1 is formed by a wet etching method, for example, it is possible to reduce the distribution of the density of the aperture area or variability of the etching rate as compared with the case where a storage portion for storing an electronic component and a storage portion for storing a via are individually formed in a core. Accordingly, consistent process accuracy is easily ensured in a plane, and it is possible to obtain a small-sized core base-material having high shape accuracy. Such an effect is effective particularly in the case where a large substrate from which a plurality of core base-materials are obtained is used, for example.

### Modified Example

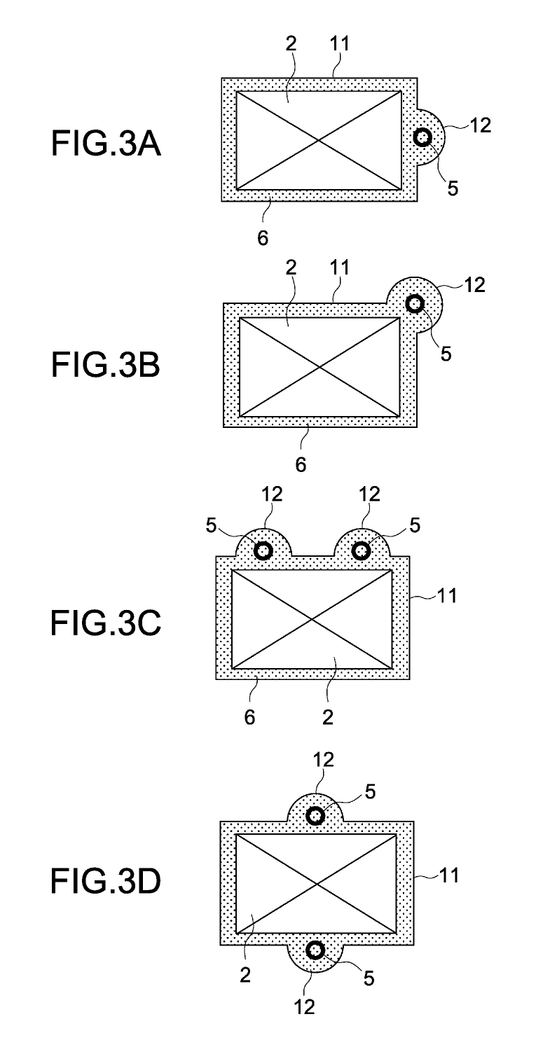

FIGS. 3A to 3D are each a schematic plan view showing a modified example of the configuration of the cavity S1. As described above, the position at which the second storage portion 12 is provided is not particularly limited, and can be appropriately set depending on the shape of the first storage portion 11, the position of the via, or the like.

For example, FIG. 3A shows an example in which the second storage portion 12 is integrally formed on the outside of a short side portion of the first storage portion 11, and FIG. 3B shows an example in which the second storage portion 12 is formed on a corner portion of the first storage portion 11. FIG. 3C shows an example in which a plurality of second storage portions are formed on a side portion of the first storage portion 11, and FIG. 3D shows an example in which the second storage portion 12 is formed on two facing sides of the first storage portion 11.

### Second Embodiment

FIG. 4 is a horizontal cross-sectional view of a main portion showing the configuration of a core base-material for a substrate with built-in electronic component according to a second embodiment of the present disclosure. Hereinafter, the configuration different from that of the first embodiment will be mainly described, and the same configuration as that according to the above-mentioned embodiment will be denoted by the same reference symbols and a description thereof will be omitted or simplified.

A core base-material 20 according to this embodiment has a cavity S2 having a configuration different from that of the cavity 51 according to the first embodiment. The cavity S2 has the first storage portion 11, the second storage portion 12, and an auxiliary aperture 14.

The auxiliary aperture 14 is formed on the four corners of the aperture 11a (first aperture) of the first storage portion 11, which has a rectangular shape. The auxiliary aperture 14 includes an aperture (third aperture) having the aperture area smaller than the second storage portion 12 (second aperture), which has a circular arc shape. The auxiliary aperture 14 is formed to have a depth equal to the depth of the first storage portion 11. The auxiliary aperture 14 is not necessarily formed on the four corners of the aperture 11a, and only has to be formed on at least one corner portion of the aperture 11a.

As described above, the first storage portion 11 is formed by wet etching of the predetermined area of the metal layer 13. Therefore, if the aperture of the first storage portion 11 has a rectangular shape, the four corners of the aperture 11a is easily formed to have a circular arc shape. Thus, because the aperture area of the first storage portion 11 is reduced, it is difficult to ensure a predetermined clearance between the four corners of the aperture 11a and the outer peripheral surface of the electronic component 2 (e.g., angular portion)

On the other hand, in this embodiment, the auxiliary aperture 14 is formed on at least one corner portion of the aperture 11 a. Therefore, it is possible to easily perform the operation of mounting (storing) the electronic component 2 in the first storage portion 11, and to ensure a predetermined clearance (minimum space) between the inner peripheral surface of the first storage portion 11 and the outer peripheral surface of the electronic component 2 after the mounting.

Furthermore, because the cavity S2 according to this embodiment has the auxiliary aperture 14, the filling efficiency of the insulating material in the cavity S2 from the auxiliary aperture 14 during the forming of the insulating layer 6 in the cavity S2 is increased. Thus, it is possible to improve the workability. Furthermore, because the auxiliary aperture 14 has the aperture area smaller than the second storage portion 12, the aperture area of the cavity S2 is not excessively increased. Therefore, it is possible to prevent the core base-material 20 from being increased in size.

The auxiliary aperture 14 is formed integrally with the first and second storage portions 11 and 12 by applying a wet etching process to the metal layer 13. Specifically, it is possible to easily form the cavity S2 in the metal layer 13 by forming a resist pattern having the shape of the aperture of the cavity S2. Therefore, because it is possible to form the cavity S2 having the auxiliary aperture 14 without increasing the man-hour, the productivity is not inhibited.

### Modified Example

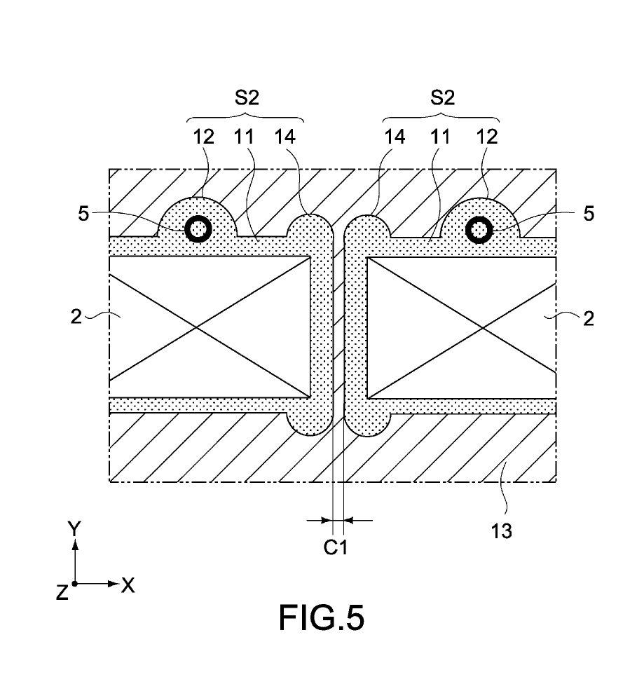

The direction in which the auxiliary aperture 14 projects is not particularly limited as long as it is directed from the four corners of the first storage portion 11 to the outside. For example, in the case where the metal layer 13 has a plurality of cavities S2 as shown in FIG. 5, the auxiliary aperture 14 may be formed along the direction (Y-axis direction) perpendicular to the direction (X-axis direction) in which two cavities S2 are opposed to each other. Accordingly, it is possible to make a space C1 between the first storage portions 11 of the cavities S2 minimum, and to make the density of the storage portion high. In particular, in the configuration example shown in FIG. 5, because the end portion of the auxiliary aperture 14 is located on the same plane with the end portion of the first storage portion 11 along the Y-axis direction, it is possible to make the effective area efficiency further high.

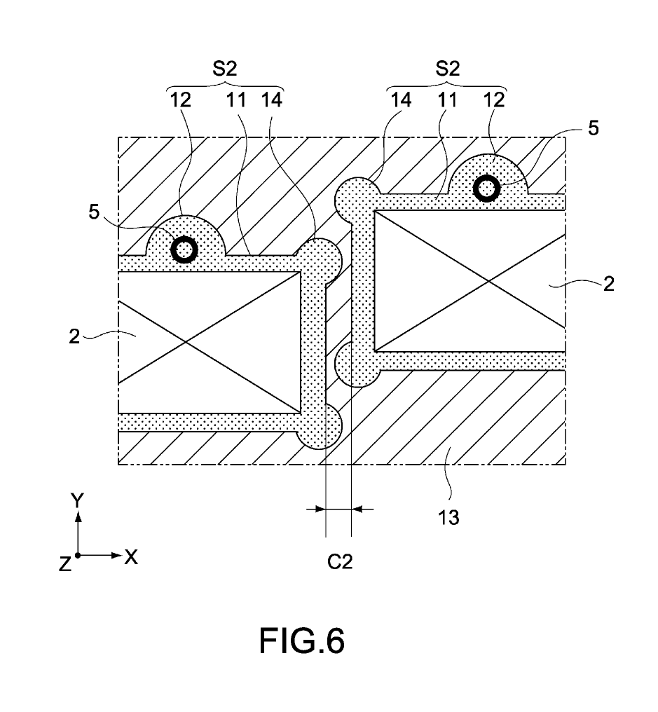

Moreover, as shown in FIG. 6, two cavities S2 adjacent to (opposed to) each other may be offset in the Y-axis direction and formed. Accordingly, it is possible to decrease the space between the first storage portions 11 of the cavities S2 and to dispose them without depending on the direction in which the auxiliary aperture 14 projects.

### Third Embodiment

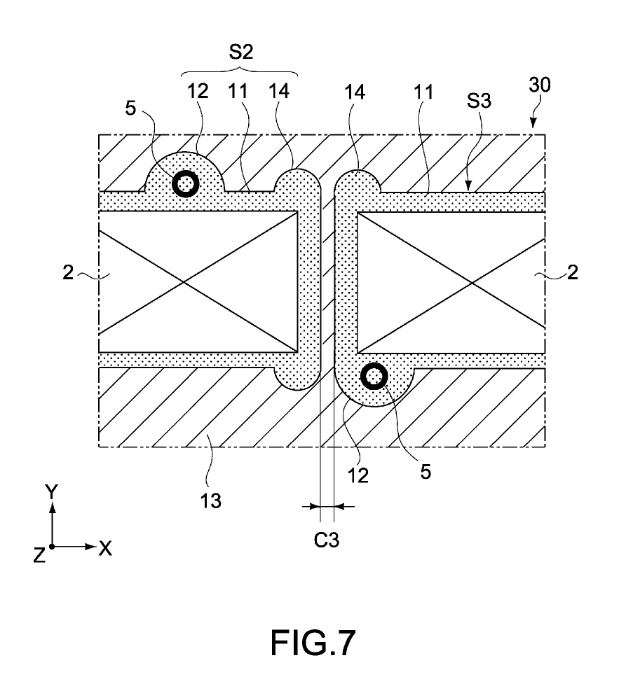

FIG. 7 is a horizontal cross-sectional view of a main portion showing the configuration of a substrate with built-in electronic component according to a third embodiment of the present disclosure. Hereinafter, the configuration different from that of the first embodiment will be mainly described, and the same configuration as that according to the above-mentioned embodiment will be denoted by the same reference symbols and a description thereof will be omitted or simplified.

This embodiment is different from the first embodiment in that a core base-material 30 according to this embodiment has the metal layer 13 in which a plurality of cavities S2 and S3 are provided. Because the cavity S2 has the same configuration as that in the second embodiment (see FIG. 5), a description thereof will be omitted, here. Hereinafter, the configuration of the cavity S3 will be described.

The cavity S3 has the first storage portion 11 having an aperture (first aperture), which has a substantially rectangular shape, and is disposed so as to face the cavity S2 in the X-axis direction. The cavity S3 has the second storage portion 12 (second aperture) and the auxiliary aperture 14 (third aperture). The second storage portion 12 is formed on a corner portion of one of two side portions of the first storage portion 11, which faces the cavity S2, and the auxiliary aperture 14 is formed on the other corner portion of the side portion. The second storage portion 12 and the auxiliary aperture 14 are formed so as to project from each corner portion to the outside along the Y-axis direction.

According to this embodiment, because the plurality of cavities S2 and S3 having different shapes are provided in the same metal layer 13, it is possible to select the optimal shape of the cavity depending on the position of storing the electronic component 2 and the position of forming the via 5. Accordingly, it is possible to contribute to the size reduction of the core base-material or improvement of the mounting density.

Moreover, in the case where the plurality of cavities S2 and S3 are disposed so as to come close to each other, it is possible to easily adjust the space C3 between the cavity S2 and the cavity S3 by changing the direction of forming the second storing portion 12 and the auxiliary aperture 14 (projection direction).

Although embodiments of the present disclosure have been described, the present disclosure is not limited to the above-mentioned embodiments and various modifications can be made without departing from the gist of the present disclosure, of course.

For example, in the above-mentioned embodiments, the first storage portion 11 is formed in a rectangular shape and the second storage portion 12 is formed in a circular arc shape. However, the shape of the aperture of each storage portion is not limited to the above-mentioned example.

Moreover, in each embodiment, the example in which a single electronic part 2 is stored in the first storage portion 11 has been described. However, a plurality of electronic parts 2 may be commonly stored in the first storage portion 11.

Furthermore, the cavities S1, S2, and S3 formed in the metal layer 13 are not necessarily employed alone, and the cavities (the cavity S1 and the cavity S2, the cavity S1 and the cavity S3, or the cavity S1, the cavity S2, and the cavity S3) may be combined as described in the third embodiment. Furthermore, in the metal layer 13, a single storage portion for storing component and/or via may be provided in addition to the cavities S1, S2, and S3.

1. A substrate with built-in electronic component, comprising:
an electronic component;
a first wiring layer having a first wiring portion;
a second wiring layer having a second wiring portion;
a via configured to electrically connect the first wiring portion and the second wiring portion; and
a core base-material having a metal layer, at least one first storage portion, and a second storage portion, the metal layer being disposed between the first wiring layer and the second wiring layer, the at least one first storage portion being formed in the metal layer, the at least one first storage portion storing the electronic component, the second storage portion being formed on an outside of the first storage portion integrally with the first storage portion, the second storage portion storing the via;
wherein the first storage portion has a first aperture having a substantially rectangular shape, and
the second storage portion has a second aperture formed on at least one side portion of the first aperture, the second aperture having a circular arc shape, and
the core base material further has third apertures formed on four corner portions of the first aperture, the third apertures having a circular arc shape and an aperture area smaller than that of the second aperture.

2-4. (canceled)

5. The substrate with built-in electronic component according to claim 1, wherein
the first storage portion has two first storage portions facing each other in a first axis direction, and
the third aperture is formed so as to project from the corner portion of the first aperture to a second axis direction perpendicular to the first axis direction.

6. A core base-material for substrate with built-in electronic component disposed between a first wiring layer and a second wiring layer, comprising:
a metal layer;
at least one first storage portion capable of storing an electronic component, the at least one first storage portion being formed in the metal layer; and
a second storage portion capable of storing a via, the second storage portion being formed on an outside of the first storage portion integrally with the first storage portion, the via being configured to electrically connect the first wiring layer and the second wiring layer;
wherein the first storage portion has a first aperture having a substantially rectangular shape,
the second storage portion has a second aperture formed on at least one side portion of the first aperture, the second aperture having a circular arc shape, and
the core base material further has a third apertures formed on four corner portions of the first aperture, the third apertures having a circular arc shape and an aperture area smaller than that of the second aperture.

7. (canceled)
